(19) United States
(12) Patent Application Publication
(10) Pub. No.: US 2025/0226298 A1
(43) Pub. Date: Jul. 10, 2025

(54) EMBEDDABLE TILES CONTAINING PASSIVE DEVICES FOR PACKAGED SEMICONDUCTOR DEVICES

(71) Applicant: Saras Micro Devices, Inc., Chandler, AZ (US)

(72) Inventor: Richard P. Sheridan, Gilbert, AZ (US)

(21) Appl. No.: 18/408,914

(22) Filed: Jan. 10, 2024

(51) Int. Cl. H01L 23/495; H01L 23/00; H01L 25/065

(52) U.S. Cl. CPC H01L 23/49589; H01L 23/4951; H01L 23/4952; H01L 23/49575; H01L 24/08; H01L 24/16; H01L 25/0652; H01L 2224/08137; H01L 2224/08146; H01L 2224/16225; H01L 2224/16227; H01L 2924/01029; H01L 2924/1431; H01L 2924/1434; H01L 2924/15311

(57) ABSTRACT

A tile for embedding components into a package substrate of a semiconductor device includes a plurality of passive devices and a polymer layer. At least two of the passive devices are individually packaged for surface mounting on first sides thereof and have respective second sides opposite the first sides, the first sides of the at least two passive devices being aligned, the second sides of the at least two passive devices being at different heights relative to the aligned first sides. The polymer layer surrounds the at least two passive devices and has a planar surface at a height that is at least as great as the heights of the second sides of the at least two passive devices.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND

The present disclosure generally relates to integrated circuits (ICs) and, more particularly, to package substrates for packaged semiconductor devices containing passive components embedded in a substrate core thereof.

Conventional methods of embedding discrete components in the core of a substrate are severely limited when it comes to attempting to embed a heterogeneous plurality of components. For one thing, there are significant challenges associated with filling large volume cavities having high numbers of components with diverse form factors with dielectric material. It is also very difficult for substrate manufacturers to form plated connections to highly variable component thicknesses/heights as part of the substrate core manufacturing process. Additionally, complex configurations involving stacked components, pre-configured parallel and series connected components, and integrated passive and active components cannot be supported. As a result, embedding of discrete components into advanced packaging substrates is practically limited to like-format components that are similar enough in size, thickness, and terminal metallization to be successfully and efficiently embedded in the core of the substrate. In the specific case of embeddable aluminum foil-based capacitors, existing methods are further limited by processes that form the capacitive electrodes from a single aluminum foil element, such that they have the same electrode materials, dielectric materials, and dielectric thickness, which limits variations in capacitive density and dielectric breakdown voltage that can be serviced.

### BRIEF SUMMARY

The present disclosure contemplates various devices and methods for overcoming the above drawbacks accompanying the related art. One aspect of the embodiments of the present disclosure is a tile for embedding components into a package substrate of a semiconductor device. The tile may comprise a plurality of passive devices, at least two of the passive devices being individually packaged for surface mounting on first sides thereof and having respective second sides opposite the first sides. The first sides of the at least two passive devices may be aligned, and the second sides of the at least two passive devices may be at different heights relative to the aligned first sides. The tile may further comprise a polymer layer surrounding the at least two passive devices and having a planar surface. The planar surface may be at a height that is at least as great as the heights of the second sides of the at least two passive devices.

The tile may comprise one or more first metal routing layers by which metal terminals on the first sides of the at least two passive devices are electrically connected to metal terminals on a first outer surface of the tile. The tile may comprise one or more second metal routing layers by which metal terminals on the second sides of the at least two passive devices are electrically connected to metal terminals on a second outer surface of the tile opposite the first. The one or more second metal routing layers may be electrically connected to the metal terminals on the second sides of one or more of the at least two passive devices by way of one or more conductive vias formed in the polymer layer. The tile may comprise either or both of the one or more first metal routing layers and the one or more second metal routing layers.

The tile may comprise a frame containing the plurality of passive devices and the polymer layer. A conductive via may be formed within the frame electrically connecting a metal terminal on a first outer surface of the tile to a metal terminal on a second outer surface of the tile opposite the first. A conductive via may be formed within the polymer layer electrically connecting a metal terminal on a first outer surface of the tile to a metal terminal on a second outer surface of the tile opposite the first. The plurality of passive devices may include stacked passive devices. The tile may comprise an array of conductive pads such as a lead frame on which the at least two passive devices are mounted.

The tile may comprise a printed circuit board (PCB) on which the at least two passive devices are mounted. The tile may comprise one or more first metal routing layers by which metal terminals on the first sides of the at least two passive devices are electrically connected to metal terminals on a first outer surface of the tile by way of one or more conductive vias formed in the PCB. The tile may comprise one or more second metal routing layers by which metal terminals on the second sides of the at least two passive devices are electrically connected to metal terminals on a second outer surface of the tile opposite the first. The one or more second metal routing layers may be electrically connected to the metal terminals on the second sides of one or more of the at least two passive devices by way of one or more conductive vias formed in the polymer layer. The plurality of passive devices may include one or more passive devices embedded in the PCB. A conductive via may be formed within the PCB electrically connecting opposing sides of the PCB. The tile may comprise a frame containing the plurality of passive devices, the polymer layer, and the PCB. A conductive via may be formed within the frame electrically connecting a metal terminal on a first outer surface of the tile to a metal terminal on a second outer surface of the tile opposite the first.

Another aspect of the embodiments of the present disclosure is a package substrate of a semiconductor device. The package substrate may comprise a substrate core and a tile embedded in the substrate core. The tile may include a plurality of passive devices, at least two of the passive devices being individually packaged for surface mounting on first sides thereof and having respective second sides opposite the first sides. The first sides of the at least two passive devices may be aligned, and the second sides of the at least two passive devices may be at different heights relative to the aligned first sides. The tile may further include a polymer layer surrounding the plurality of passive devices and having a planar surface. The planar surface may be at a height that is at least as great as the heights of the second sides of the at least two passive devices.

A thickness of the tile may match a thickness of the substrate core. Advantageously, this may simplify the process of embedding the tile in the substrate core. The plurality of passive devices may define a plurality of decoupling capacitors in relation to an integrated circuit to be mounted on the package substrate. The plurality of passive devices may define an integrated voltage regulator (IVR) in relation to an integrated circuit to be mounted on the package substrate.

Another aspect of the embodiments of the present disclosure is a tile grid for manufacturing a plurality of tiles for embedding components into a package substrate of a semiconductor device. The tile grid may comprise a frame having a plurality of cutout regions defining a plurality of cells, each of the cells containing a plurality of passive devices. The tile grid may further comprise a plurality of polymer layers respectively filling the plurality of cells, each of the polymer layers surrounding the respective plurality of passive devices and having a planar surface.

In each of the cells, at least two of the passive devices may be individually packaged for surface mounting on first sides thereof and may have respective second sides opposite the first sides. The first sides of the at least two passive devices may be aligned, and the second sides of the at least two passive devices may be at different heights relative to the aligned first sides. In each of the cells, the planar surface of the polymer layer may be at a height that is at least as great as the heights of the second sides of the at least two passive devices.

In each of the cells, the plurality of passive devices may include a stack of two or more unpackaged capacitors. Each of the cells may further contain a plurality of metal terminals. The plurality of metal terminals may include two or more first metal terminals electrically isolated from each other and electrically connected to respective first electrodes of the two or more unpackaged capacitors. The plurality of metal terminals may further include a shared second metal terminal electrically connected to the second electrodes of the two or more unpackaged capacitors.

Another aspect of the embodiments of the present disclosure is a method of manufacturing a tile for embedding components into a package substrate of a semiconductor device. The method may comprise surrounding at least two passive devices with a polymer layer, the at least two passive devices being individually packaged for surface mounting on first sides thereof and having respective second sides opposite the first sides. The first sides of the at least two passive devices may be aligned, and the second sides of the at least two passive devices may be at different heights relative to the aligned first sides. The polymer layer may have a planar surface at a height that is at least as great as the heights of the second sides of the at least two passive devices. The method may further comprise singulating a tile comprising the polymer layer and a plurality of passive devices including the at least two passive devices.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1A is a perspective view of a tile grid defining a plurality of cells for manufacturing a plurality of tiles containing various components;

FIG. 1B is a cross-sectional view taken along the line 1B-1B in FIG. 1A;

FIG. 1C is an alternative cross-sectional view taken along the line 1B-1B in FIG. 1A;

FIG. 2A is a perspective view of the tile grid at another stage in manufacturing the plurality of tiles;

FIG. 2B is a cross-sectional view taken along the line 2B-2B in FIG. 2A;

FIG. 2C is an alternative cross-sectional view taken along the line 2B-2B in FIG. 2A;

FIG. 3A is a perspective view of the tile grid at another stage in manufacturing the plurality of tiles;

FIG. 3B is a cross-sectional view taken along the line 3B-3B in FIG. 3A;

FIG. 3C is an alternative cross-sectional view taken along the line 3B-3B in FIG. 3A;

FIG. 4A is a perspective view of the tile grid at another stage in manufacturing the plurality of tiles;

FIG. 4B is a perspective view of an individual tile from among the plurality of tiles;

FIG. 5 is a cross-sectional view of the tile embedded in the core of a package substrate;

FIG. 6 is a cross-sectional view of the package substrate showing the tile embedded in the core thereof;

FIG. 7 is a cross-sectional view showing a variant of the tile shown in FIG. 3B;

FIG. 8 is a cross-sectional view showing a variant of the tile shown in FIG. 3B;

FIG. 9 is a cross-sectional view showing a variant of the tile shown in FIG. 3B;

FIG. 10 is a cross-sectional view showing a variant of the tile shown in FIG. 3B;

FIG. 11 is a cross-sectional view showing a variant of the tile shown in FIG. 3B;

FIG. 12 is a cross-sectional view showing a variant of the tile shown in FIG. 3B;

FIG. 13 is a cross-sectional view showing a variant of the tile shown in FIG. 3B;

FIG. 14 is a cross-sectional view showing a variant of the tile shown in FIG. 3B;

FIG. 15 is a cross-sectional view showing a variant of the tile shown in FIG. 3C;

FIG. 16A is a perspective view of another tile grid defining a plurality of cells for manufacturing a plurality of tiles containing various components;

FIG. 16B is a cross-sectional view taken along the line 16B-16B in FIG. 16A;

FIG. 17A is a perspective view of the tile grid at another stage in manufacturing the plurality of tiles;

FIG. 17B is a cross-sectional view taken along the line 17B-17B in FIG. 17A;

FIG. 18A is a perspective view of the tile grid at another stage in manufacturing the plurality of tiles;

FIG. 18B is a cross-sectional view taken along the line 18B-18B in FIG. 18A;

FIG. 18C is a perspective view of an individual tile from among the plurality of tiles;

FIG. 19A is a perspective view of a tile grid defining a plurality of cells for manufacturing a plurality of tiles containing stacked capacitors;

FIG. 19B is a cross-sectional view taken along the line 19B-19B in FIG. 19A;

FIG. 19C is an alternative cross-sectional view taken along the line 19B-19B in FIG. 19A;

FIG. 20A is a perspective view of the tile grid at another stage in manufacturing the plurality of tiles;

FIG. 20B is a cross-sectional view taken along the line 20B-20B in FIG. 20A;

FIG. 20C is an alternative cross-sectional view taken along the line 20B-20B in FIG. 20A;

FIG. 20D is a close up view of a portion of FIG. 20B;

FIG. 21A is a perspective view of the tile grid at another stage in manufacturing the plurality of tiles;

FIG. 21B is a cross-sectional view taken along the line 21B-21B in FIG. 21A;

FIG. 21C is an alternative cross-sectional view taken along the line 21B-21B in FIG. 21A;

FIG. 22A is a perspective view of the tile grid at another stage in manufacturing the plurality of tiles;

FIG. 22B is a cross-sectional view taken along the line 22B-22B in FIG. 22A;

FIG. 22C is an alternative cross-sectional view taken along the line 22B-22B in FIG. 22A;

FIG. 23A is a perspective view of the tile grid at another stage in manufacturing the plurality of tiles;

FIG. 23B is a perspective view of an individual tile from among the plurality of tiles;

FIG. 24 is a cross-sectional view showing a variant of the tile shown in FIG. 22B;

FIG. 25 is a cross-sectional view showing a variant of the tile shown in FIG. 22B;

FIG. 26 is a cross-sectional view showing a variant of the tile shown in FIG. 22B;

FIG. 27 is a cross-sectional view showing a variant of the tile shown in FIG. 22B;

FIG. 28 is a cross-sectional view showing a variant of the tile shown in FIG. 22B; and

FIG. 29 is a cross-sectional view showing stacking of a plurality of tiles.

### DETAILED DESCRIPTION

The present disclosure encompasses various embodiments of tile grids and tiles for embedding components into a package substrate of a semiconductor device, along with methods of manufacture thereof. The detailed description set forth below in connection with the appended drawings is intended as a description of several currently contemplated embodiments and is not intended to represent the only form in which the disclosed subject matter may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

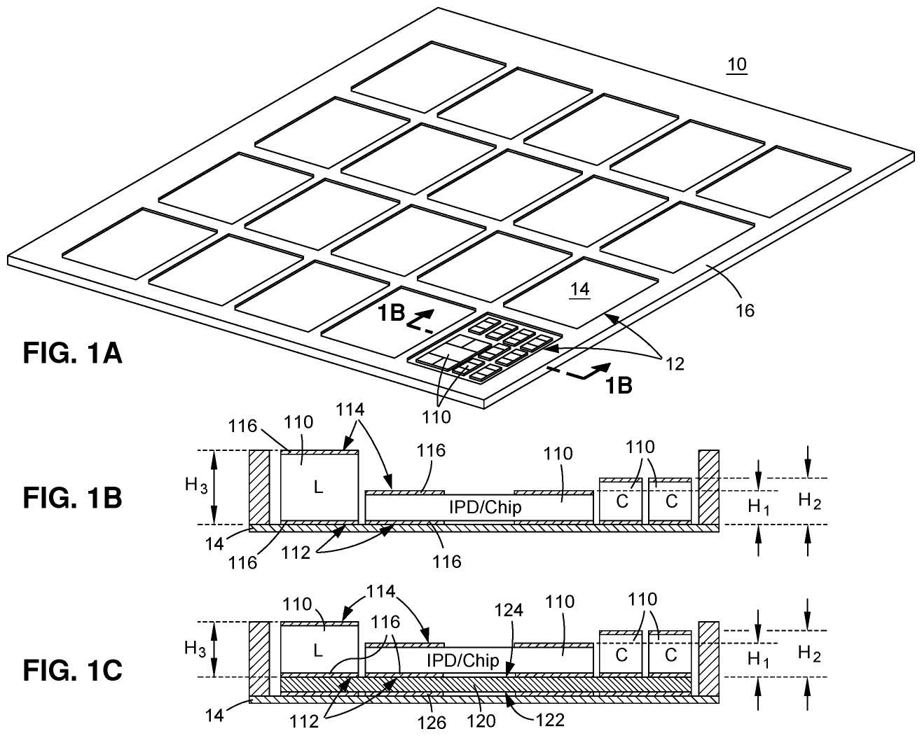

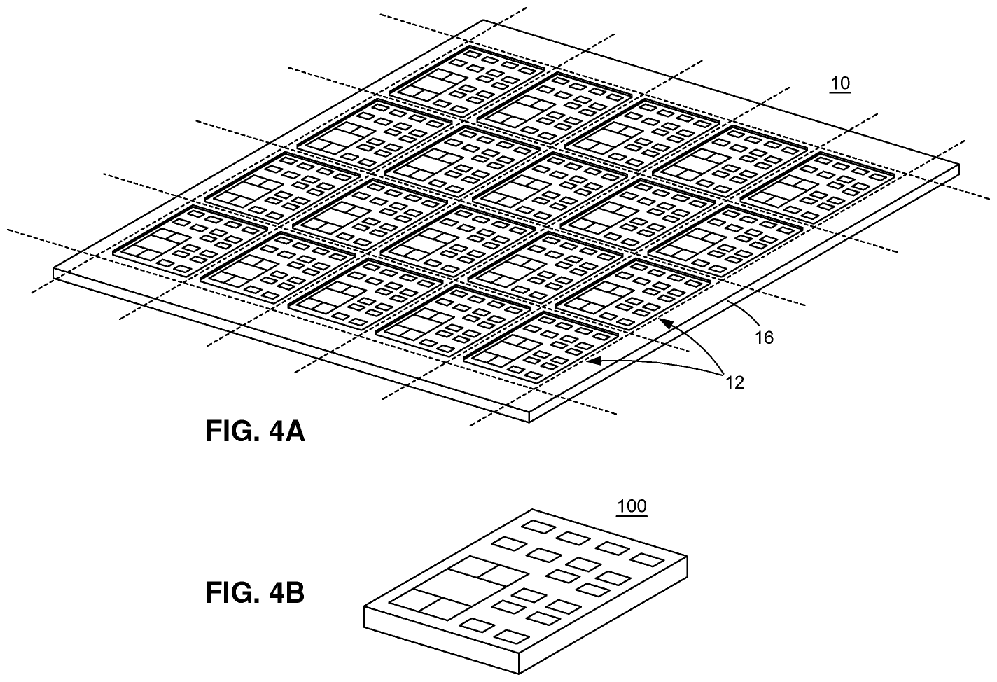

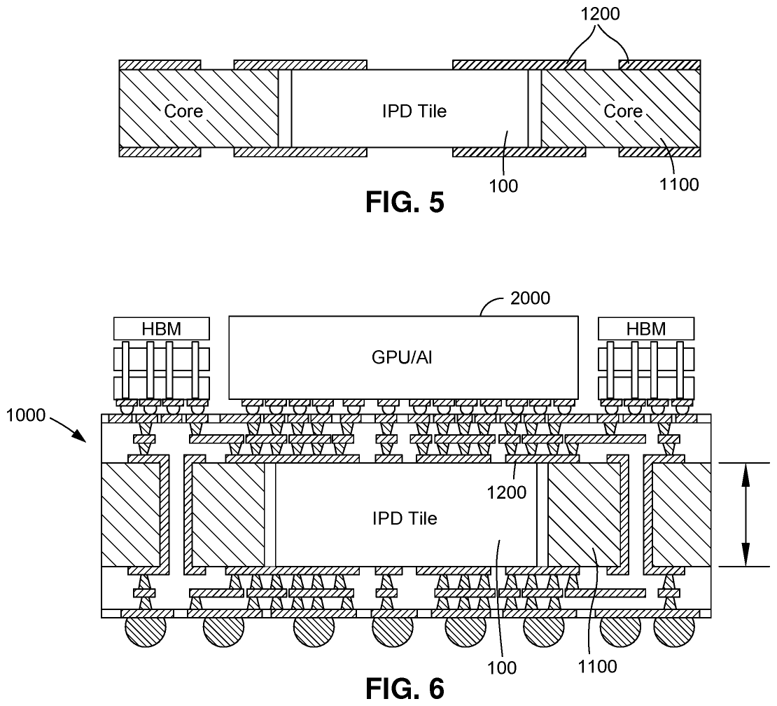

FIG. 1A is a perspective view of a tile grid 10 defining a plurality of cells 12 (e.g., a matrix of cells 12) for manufacturing a plurality of tiles 100 (see FIGS. 4A and 4B) containing various components. As represented in FIGS. 5 and 6, one or more such tiles 100 may thereafter be conveniently embedded into the substrate core 1100 of a package substrate 1000 for an integrated circuit 2000 (such as the illustrated GPU/AI with HBM memory), eliminating the challenges associated with embedding the individual components as discrete elements. Advantageously, the tiles 100 may be pre-tested prior to embedding to reduce any potential yield loss associated with attempting to do complex integrated embedding as an in-situ element of the package substrate process.

At the manufacturing stage represented in FIG. 1A, a backing film 14 such as an adhesive tape has been attached to a frame 16 having a plurality of cutout regions (rectangular regions in this example) defining the cells 12 of the tile grid 10. One of the cells 12 has been populated with a plurality of passive devices 110 in a desired configuration which may be custom designed for a particular application. The plurality of passive devices 110 may be used as decoupling/bypass capacitors, for example, to be embedded in the package substrate core 1100 at a position closer to the die 2000 for smaller voltage step-down to decrease voltage ripple and resistive losses. As another example, the plurality of passive devices 110 may define a voltage regulator, driver, or other power delivery architectural element, in which case the plurality of devices 110 may include an integrated passive device (IPD) such as an RC circuit along with at least one discrete passive. Referring to the cross-sectional view of FIG. 1B, each of the passive devices 110 (which may include inductors L, capacitors C, IPDs, etc. as illustrated), may be individually packaged for surface mounting on first sides 112 thereof and may have respective second sides 114 opposite the first sides 112. The first sides 112 of some or all of the passive devices 110 may be aligned, for example, by being attached to the backing film 14. Alternatively, as shown in FIG. 1C, the passive devices 110 may first be mounted to a printed circuit board (PCB) 120, with the first sides 112 thus being aligned where they abut the PCB 120. Advantageously, the disclosed subject matter contemplates populating the cells 12 with a variety of different types of passive devices 110 that may be made by different manufacturers, for example, and may have heterogeneous shapes and sizes. As such, the second sides 114 of some or all of the passive devices 110 may be at different heights H₁, H₂, H₃ relative to the aligned first sides 112.

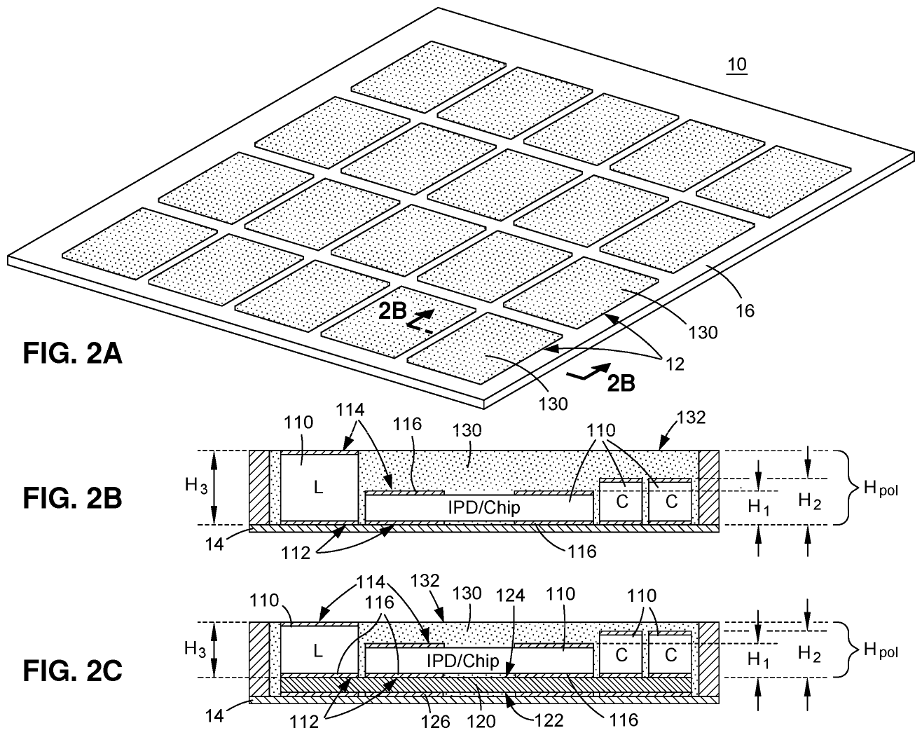

Referring to FIG. 2A, after the cells 12 of the tile grid 10 have been populated with the passive devices 110 (with each cell 12 having the same or a different configuration of passive devices 110 as desired), the passive devices 110 in each cell 12 may be encapsulated with a polymer layer 130 such as an epoxy resin. As shown in the cross-sectional view of FIG. 2B (as well as in FIG. 2C including the optional PCB 120), the polymer layer 130 may surround the plurality of passive devices 110 and may advantageously have a planar surface 132 that is at a height Hₚₒₗ (defined relative to the aligned first sides 112 of the passive devices 110) that is at least as great as the heights H₁, H₂, H₃ of the second sides 114 of the passive devices 110. The polymer layer 130 may in some cases be planarized (e.g., by a grinding process) to produce the planar surface 132. In this particular example, the height Hₚₒₗ is greater than the height H₁ of the illustrated IPD/Chip and is greater than the height H₂ of the two illustrated capacitors C, while being equal to the height H₃ of the illustrated inductor L. In this way, the polymer layer 130 may, at least in part, define an upper border that is at a consistent height Hₚₒₗ relative to the aligned first sides 112 of the passive devices 110, effectively eliminating the height disparity between the various passive devices 110. If a greater overall height is desired (e.g., in order to match a target substrate core thickness), the polymer layer 130 may be made higher, covering all of the passive devices 110 in some cases.

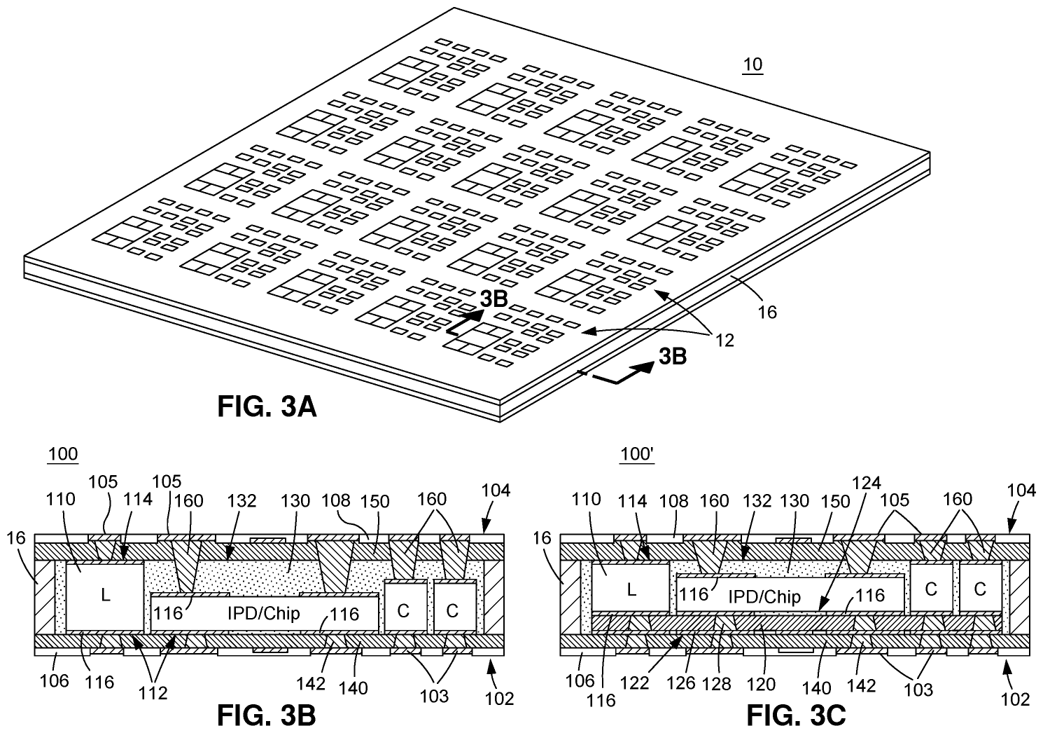

Referring to FIGS. 3A-3C, it is contemplated that various steps may be performed to build up additional metal routing layers for pre-connecting the passive devices 110 in any electrical/circuit configuration that may be desired. For example, after the passive devices 110 have been encapsulated by the polymer layer 130 as described above in relation to FIGS. 2A-2C, any buried terminals 116 (e.g., terminal pads) on the second sides 114 of the passive devices 110 (i.e., opposite the terminals 116 on the aligned sides 112) may be exposed by a planarization process (e.g., grinding) and/or a laser via formation process. Meanwhile, the terminals 116 on the first sides 112 of the passive devices 110 (or terminals 126 on the PCB 120 in the case of the tile 100′ including the optional PCB 120) may be exposed simply by peeling off or otherwise removing the backing film 14. As illustrated in FIGS. 3B and 3C, one or more first metal routing layers 140 may then be formed to electrically connect metal terminals 116 on the first sides 112 of the passive devices 110 to metal terminals 103 on a first outer surface 102 of the tile 100 being produced. In the case of the tile 100′ in which the passive devices 110 are on the optional PCB 120, the first metal routing layer(s) 140 may electrically connect a metal contact 126 on an underside of the PCB 120 (i.e., opposite the passive devices 110) to the metal terminals 103 on the first outer surface 102 of the tile 100′. The first metal routing layer(s) 140 may be formed in a polymer dielectric material, for example, and may establish the electrical connections by way of one or more conductive vias 142 formed therein (with the electrical connections additionally including one or more conductive vias 128 formed in the PCB 120 in the case of the tile 100′).

As also illustrated in FIGS. 3B and 3C, the tile 100, 100′ may further include one or more second metal routing layers 150 by which metal terminals 116 on the second sides 114 of the passive device(s) 110 may be electrically connected to metal terminals 105 on a second outer surface 104 of the tile 100, 100′ opposite the first outer surface 102. Like the first metal routing layer(s) 140, the second metal routing layer(s) 150 may be formed in a polymer dielectric material, for example, and may establish the electrical connections by way of one or more conductive vias 160 formed therein. In the case of passive device(s) 110 that are buried by the polymer layer 130, the conductive vias 160 may further extend through the polymer layer 130 (or there may be conductive vias 160 that extend only through the polymer layer 130 if no second metal routing layers 150 are included). In the case of passive device(s) 110 that are not buried by the polymer layer 130, (such as the inductor L shown in FIGS. 3B and 3C), the conductive vias 160 may extend only through the second metal routing layer(s) 150 as shown. It is also contemplated that the one or more second metal routing layers 150 may be included while the one or more first metal routing layers 140 are omitted. For example, in the example shown in FIG. 3C, the first metal routing layer(s) 140 may be omitted, with routing being provided by the PCB 120 and/or additional layers built up after embedding the tile 100′ in the package substrate 1000.

Additional build-up layers are also contemplated, such as a solder mask 106, 108 or other layer for selectively covering areas of the conductive circuit elements while exposing surfaces for soldering or forming plated connections. Such additional layers may be particularly useful for non-embedded applications, such as where the tile 100, 100′ may be surface mounted.

Finally, the tile grid 10, which may comprise a panel or sheet of tiles 100, 100′ and the surrounding frame 16, may be diced as represented by the dashed lines in FIG. 4A, thus singulating individual tiles 100, 100′ as illustrated in FIG. 4B. The singulated tile 100, 100′ may then be embedded in the substrate core 1100 of a package substrate 1000 as shown in FIGS. 5 and 6 (e.g., a flip-chip BGA package as illustrated), with the metal terminals 103, 105 on the outer surfaces 102, 104 of the tile 100, 100′ being electrically connected to the metal routing layers of the package substrate 1000. The connection to the package substrate 1000 can be lateral using plating 1200 (e.g., copper plating) from the tile 100, 100′ to a metal (e.g., copper) plane on the substrate core 1100, with the plating 1200 extending over an intervening anchoring epoxy in some cases. Alternatively, or in addition to, the connections to the package substrate 1000 can be through vias to subsequent build-up layers. In general, pre-forming passive elements including IPD/IVR elements into tiles as a pre-cursor to substrate embedding may beneficially add many additional degrees of freedom in the diversity/heterogeneity of components that can be integrated together. These pre-formed tiles may have planar terminal connections customized in thickness to be matched to the substrate core targeted for embedding, greatly simplifying the embedding process. Additionally, these tiles can be pre-tested prior to embedding into the package substrate to reduce any potential yield loss of the entire package substrate panel.

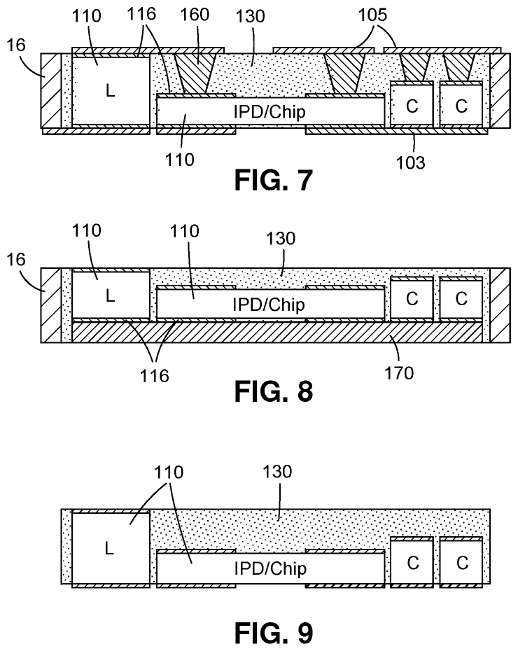

FIGS. 7-15 show additional variants of the tile 100, 100′. In FIG. 7, an example is shown in which the optional layer build-up described in relation to FIGS. 3A-3C is omitted. As illustrated, the one or more first metal routing layers 140 and/or second metal routing layers 150, solder mask 106, 108, etc. may thus be omitted, with the metal terminals 103, 105 of the tile 100, 100′ being formed directly on the metal terminals 116 of the passive devices 110 and/or on the polymer layer 130. In particular, in the case of passive device(s) 110 that are buried by the polymer layer 130, the tile 100, 100′ may include conductive vias 160 that extend through the polymer layer 130 as described above to electrically connect the metal terminals 116 on the buried passive devices 110 with the metal terminals 105 of the tile 100, 100′. The variant shown in FIG. 7 may represent a completed and singulated tile 100 (or tile 100′ if the PCB 120 is included) that may then be embedded in the substrate core 1100 of a package substrate 1000 as described above.

FIG. 8 is an example in which some or all of the passive devices 110 are mounted on a lead frame 170. The lead frame 170 may be used in place of the PCB 120 shown in FIG. 1C, for example, and may similarly be placed on the backing film 14, which may then be removed after the polymer layer 130 is provided (after which optional layer build-up may be provided as described in relation to FIGS. 3A-3C as desired). Like the PCB 120, the lead frame 170 may provide electrical connections among the passive devices 110 and/or between the passive devices 110 and the outside of the tile 100, 100′.

FIG. 9 shows a frameless example that may be the same as the tile 100, 100′ described above except that the frame 16 may be completely omitted from the tile array 10. To produce this variant, the cells 12 of the tile grid 10 may be defined arbitrarily by placement of the passive devices 110 as desired, rather than by cutout regions of a frame 16. The polymer layer 130 may then be filled over all of the cells 12 at once, and the cells 12 may be singulated by cutting through the polymer layer 130 itself (rather than through the frame 16 as described above).

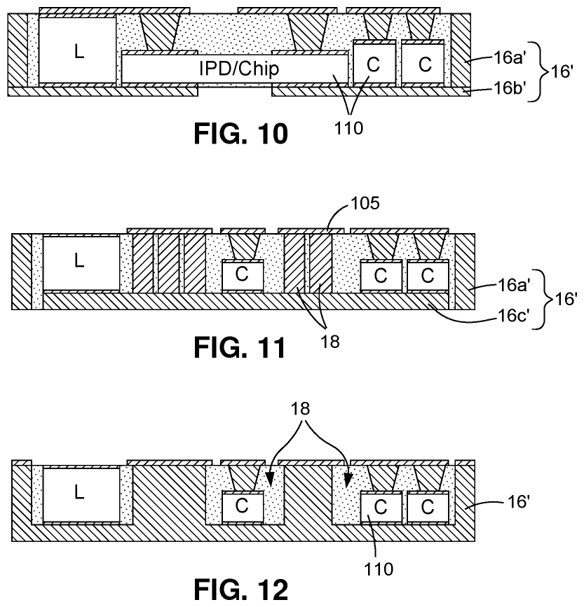

FIGS. 10-12 illustrate variants of the tile 100, 100′ in which an electrically and thermally conductive framing element 16′ is used. In FIG. 10, the framing element 16′ includes, in addition to a conductive frame 16a′ defining the boundaries of the cells 12, a conductive backing plate 16b′ on which the passive devices 110 may be mounted. The conductive backing plate 16b′ may be provided on the backing film 14 shown in FIG. 2B, for example. FIG. 11 shows a variant in which the framing element 16′ includes the conductive frame 16a′ and a heat spreader base 16c′, which may additionally serve as ground and may be electrically connected to the metal terminals 105 by conductive pillars 18 embedded in the tile 100, 100′. FIG. 12 shows a further variant in which the framing element 16′ is formed out of a single piece of electrically and thermally conductive material that has been milled to produce cavities 16d′ within which the passive devices 110 are mounted.

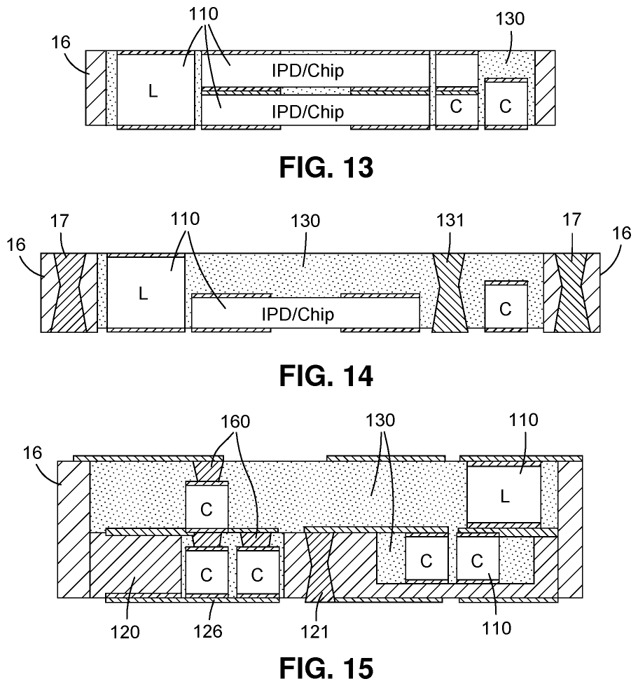

FIG. 13 is provided to illustrate the possibility of stacking passive devices 110 within each cell 12 of the tile grid 10, thus producing a tile 100, 100′ including stacked passive devices 110. Advantageously, the stacking of passive devices 110 may reduce the footprint of the tile 100, 100′, which may, for example, allow for increased capacitance within the same area near the integrated circuit 2000 to be mounted on the package substrate 1000 (see FIG. 6). It should be noted, in the case of stacked passive devices 110 (such as the stacked IPD/Chip shown in FIG. 13), that the entire stack may in some cases be defined to have a first side 112 (i.e., the bottom of the lowermost device 110 of the stack) that is aligned with the first sides 112 of other passive devices 110 (and may abut the backing film 14, PCB 120, or lead frame 170, for example) and a second side 114 (i.e., the top of the uppermost device 110 of the stack) that may or may not be buried by the polymer layer 130 as described above.

Referring to FIG. 14, it is further contemplated that any of the various tiles 100, 100′ described herein may include one or more pass-through vias 17 formed within the frame 16 and/or one or more pass-through vias 131 formed within the polymer layer 130. The pass-through vias 17, 131 may comprise a conductive via fill provided within a drilled hole and may allow for pass-through electrical connections as may be needed depending on the particular application.

FIG. 15 is provided to illustrate the possibility of embedding some of the passive components 110 within the PCB 120 of the tile 100′. A conductive through via 121 is also shown illustrating that pass-through electrical connections may be made from one side of the PCB 120 to the other as needed depending on the particular application.

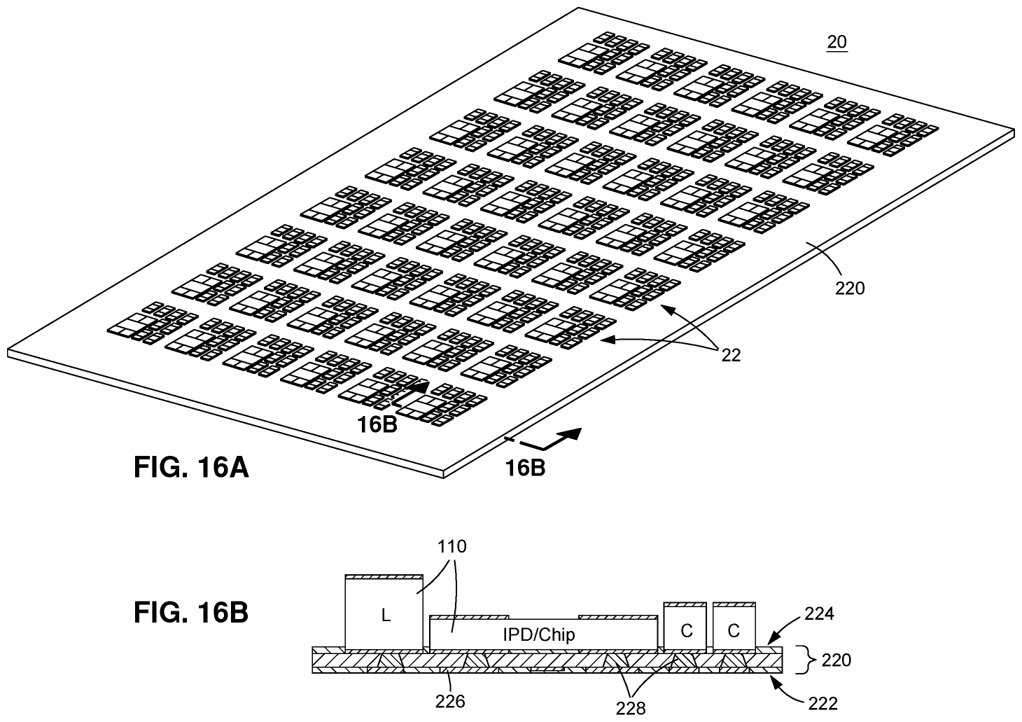

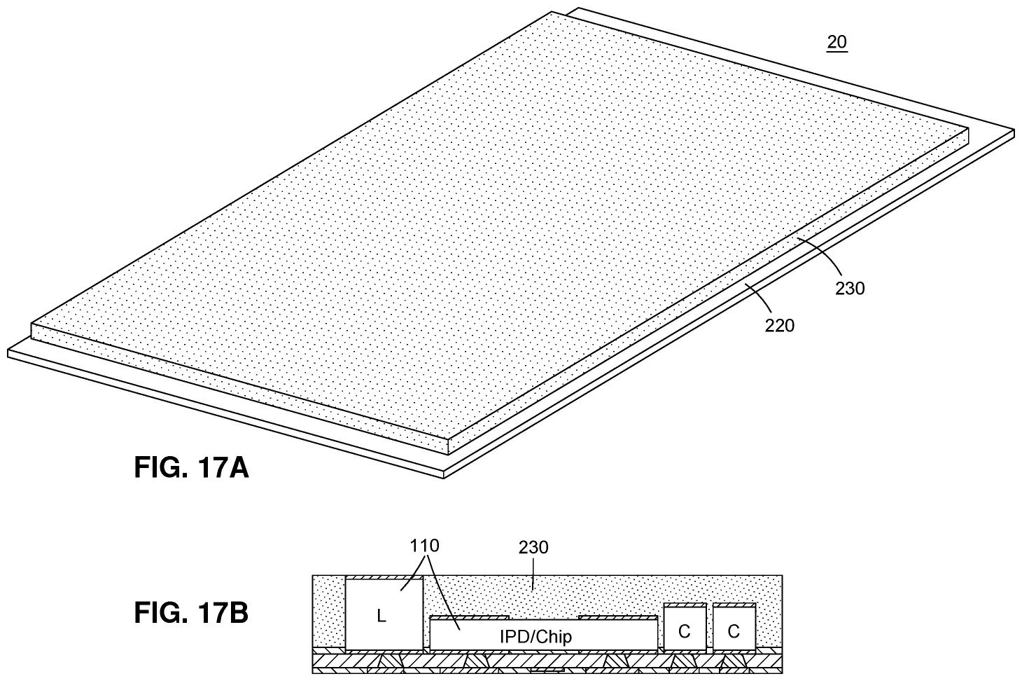

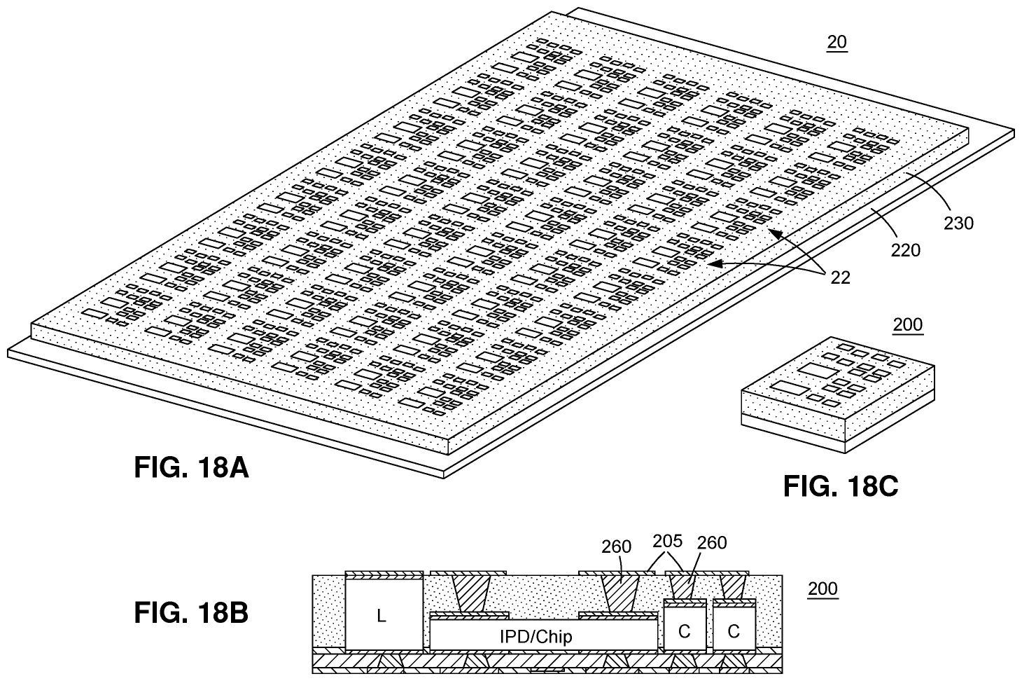

Referring to FIGS. 16A-18C, another variation on the processes and tiles 100, 100′ described herein may begin with formation of an entire tile grid 20 on the same continuous PCB 220. Similar to the frameless example described above in relation to FIG. 9, the cells 22 of the tile grid 20 may be defined arbitrarily by placement of the passive devices 110 as desired, rather than by cutout regions of a frame 16. FIG. 16A shows the initial mounting of passive devices 110 on the PCB 220 in an arrangement of cells 22, with 16B showing a cross-sectional view of one such cell 22. The PCB 220 may be the same as the PCB 120 of the tile 100′ except that it may extend continuously under the entire tile grid 20 in place of a backing film 14 (rather than being placed in an individual cell 12 on a backing film 14 as shown in FIG. 1C). The PCB 220 may include a first side 222 and a second side 224, with the second side 224 (top, in FIG. 16B) being the side on which the passive devices 110 are mounted. The PCB 220 may further include one or more metal contacts 226 on the first side 222 thereof and may include one or more pass-through vias 228. The polymer layer 230 may then be filled over all of the cells 22 at once as shown in FIGS. 17A and 17B, and metal terminals 205 and conductive vias 260 may be formed as shown in FIGS. 18A and 18B (along with optional layer build-up as described above) to connect the passive devices 110 to the outside of the resulting tile 200, which may be singulated as shown in FIG. 18C.

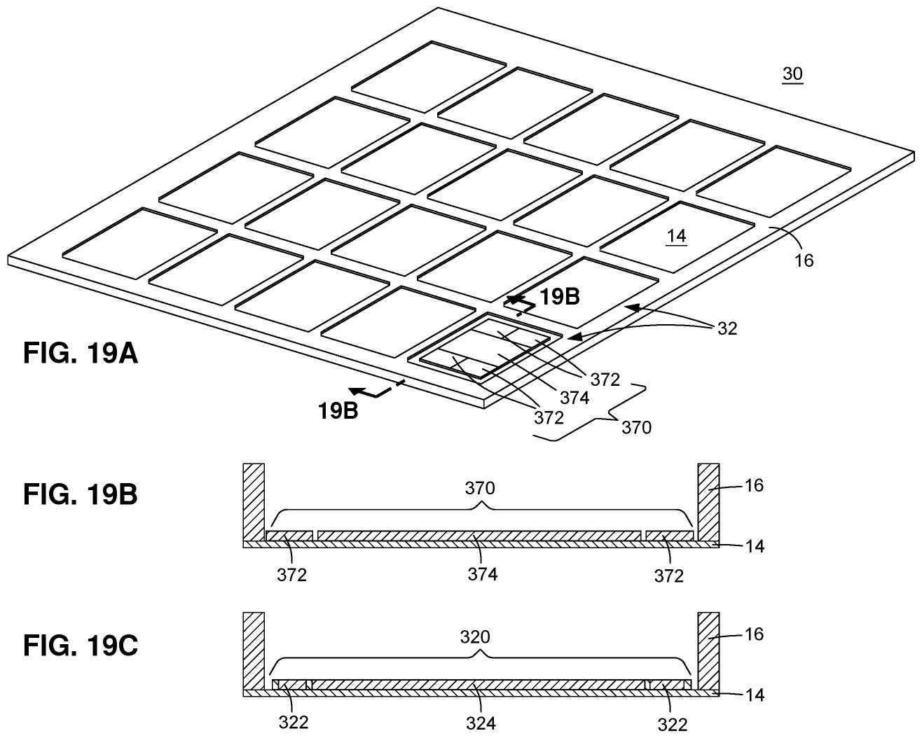

FIG. 19A is a perspective view of a tile grid 30 defining a plurality of cells 32 for manufacturing a plurality of tiles 300 (see FIGS. 23A and 23B) containing, in particular, stacked capacitors. Like the tiles 100, 100′, 200 described above, one or more such tiles 300 may thereafter be conveniently embedded into the substrate core 1100 of a package substrate 1000 for an integrated circuit 2000 as represented in FIGS. 5 and 6. The tiles 300 may similarly be pre-tested prior to embedding and in some cases may themselves be stacked to further increase the capacitance within the same footprint. Advantageously, the capacitive elements within a single tile 300 may be arrayed so as to service multiple voltage domains in a power delivery network (PDN) while being in a form factor that enables stacking and/or embedding in the package substrate 1000. The disclosed subject matter may allow for the integrations of separately manufactured capacitive elements potentially diverse in metallization, dielectric materials, and dielectric thicknesses brought together and integrated into a tile post-manufacturing. This may allow for a greater variety of capacitive densities, dielectric thicknesses, and dielectric materials to be used to service a broader range of domain voltages without sacrificing capacitive density. These tiles 300 can be custom configured in a wide range of thicknesses to match package substrate core thicknesses enabling them to be embedded in a wider variety of semiconductor packaging applications. Moreover, the rigidity of these tiles 300 may enable finished tiles 300 to be stacked on one-another prior to, or during, the package substrate embedding process.

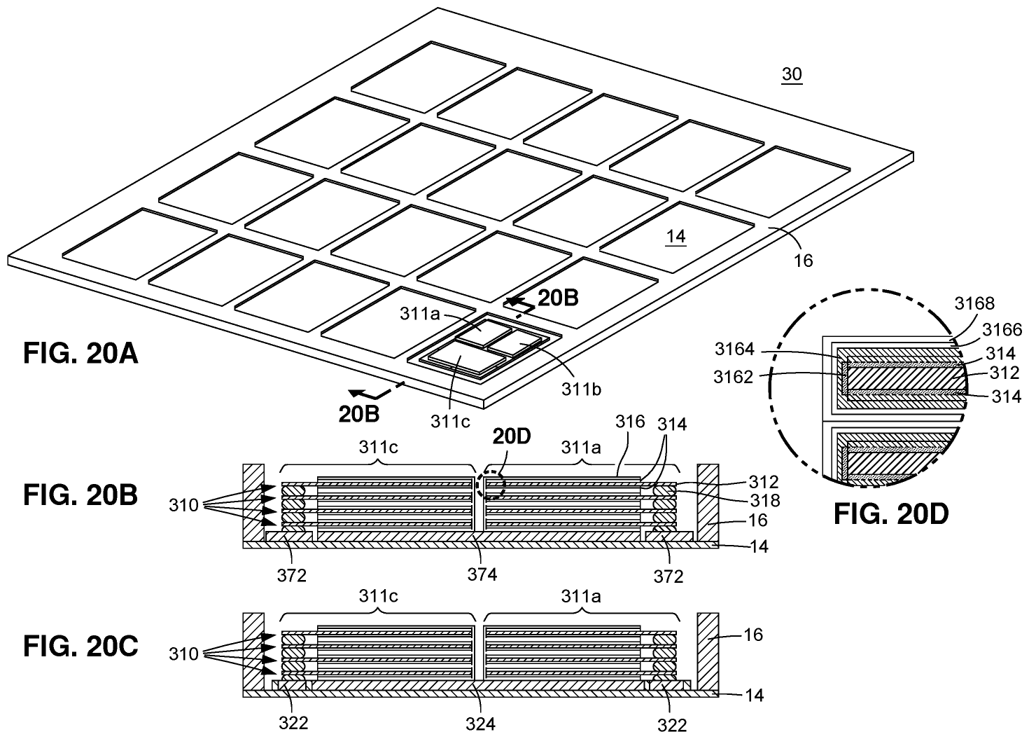

At the manufacturing stage represented in FIG. 19A, a backing film 14 has been attached to a frame 16 having a plurality of cutout regions as in the case of the tile grid 10 described above, in this case defining the cells 32 of the tile grid 30. One of the cells 32 has been provided with a plurality of electrically isolated metal terminals 372, 374, which may be terminals of a lead frame 370 as represented in FIGS. 19A and 19B or may be discrete terminal pads (e.g., squares of metal such as copper) individually positioned on the backing film 14 as desired. FIG. 19C illustrates a further alternative in which each cell 32 is provided with a PCB 320 having electrically isolated terminals 322, 324 in place of the terminals 372, 374. In the depicted layout, four first terminals 372 are provided that are electrically isolated from each other and arranged on either side of the cell 32, and a single second terminal 374 is provided in the middle of the cell 32. As shown in FIGS. 20A-20C, a plurality of capacitors 310 may be arranged as discrete capacitor stacks 311a, 311b, 311c, etc. that may service respective voltage domains associated with the different terminals 372, 374, 322, 324 of the lead frame 370 or PCB 320 (or discrete terminals). It is contemplated that the capacitors 310 (and stacks 311 thereof) may be in a semi-finished, unencapsulated, unpackaged state when they are placed in the cell 32.

Each individual capacitor 310 or capacitive element may comprise a conductive substrate 312 serving as a first electrode (e.g., anode) that is made of aluminum, an aluminum alloy, or another material (e.g., tantalum) that is etched or otherwise modified to have a high surface area, such as an etched aluminum foil as described in Applicant's own U.S. Patent Application Pub. No. 2023/0067888 (“the '888 publication”), entitled “Planar High-Density Aluminum Capacitors for Stacking and Embedding,” the entire contents of each of which is incorporated by reference herein. Alternative or additional modifications to increase the surface area of the conductive substrate 312 may include deposition of a sintered aluminum powder or other aluminum, aluminum oxide, titanium, or titanium oxide powder thereon. The conductive substrate 312 may be a metal foil as described in Applicant's own U.S. Patent Application Pub. No. 2023/0073898, entitled “Modified Metal Foil Capacitors and Methods for Making Same,” the entire contents of which is incorporated by reference herein. As illustrated, the conductive substrate 312 may thus comprise a solid metal portion (represented by reference number 312) and a high surface area (HSA) portion 314 on front and back sides thereof. A layer buildup 316 may then be formed on the HSA portion 314 wrapping around the conductive substrate 312 on both sides.

More specifically, as shown in FIG. 20D, the HSA portion 314 of the conductive substrate 312 may include, conformal therewith, a dielectric layer 3162 such as a naturally occurring oxide layer (e.g., an aluminum oxide layer) or one that has been grown by an anodization process (e.g., by placing the conductive substrate 312 in an electrolytic solution and passing a current through the solution), grown by thermal oxidation in a humidity chamber, or coated on the conductive substrate 312 (e.g., by atomic layer deposition). As may be appreciated, the dielectric layer 3162 may, in general, exhibit the same high surface area as the underlying HSA portion 314 of the conductive substrate 312 as it fills in and takes the shape of the various tunnels and recesses that may result from the etching or other modification to the material of the conductive substrate 312. As shown, a portion of the dielectric layer 3162 may also be formed directly on the solid metal portion as it wraps around the edge of the conductive substrate 312. The HSA portion 314 of the conductive substrate 312 may further include, conformal therewith, a conductive polymer layer 3164 that is electrically isolated from the conductive substrate 312 by the dielectric layer 3162 and may exhibit the same high surface area as the underlying conductive substrate 112 as it fills in and takes the shape of the various tunnels and recesses that may result from the etching or other modification to the material of the conductive substrate 112, with the dielectric layer 3162 sandwiched therebetween. The conductive polymer layer 3164 may serve as a second electrode (e.g., cathode) of the capacitor 110. Similarly to the dielectric layer 3162, a portion of the conductive polymer layer 3164 may wrap around the edge of the conductive substrate 312, but with the dielectric layer 3162 therebetween as shown. A variety of conductive polymers may be suitable for use as the conductive polymer layer 3162 serving as the second electrode of the capacitor 110 described herein. The conductive polymer layer may, for example, comprise one or more of a polypyrrole, a polythiophene, a polyaniline, a polyacetylene, a polyphenylene, a poly(p-phenylene-vinylene), PEDOT:PSS (poly(3,4-ethylenedioxythiophene) polystyrene sulfonate), or P3HT (poly(3-hexylthiophene-2,5-diyl)). In some cases, TiN or Pt may be used in place of the conductive polymer.

In addition to the dielectric layer 3162 and the conductive polymer layer 3164 serving as the second electrode (e.g., cathode), the layer buildup 316 may include additional layers on the conductive polymer layer 3164 in order to improve the electrical connection between the conductive polymer layer 3164 and the metal terminals 372, 374. For example, a carbonaceous layer 3166 (e.g., a carbon ink) and/or a metallization layer 1368 (e.g., Ag or Ti/Cu) may be applied on the conductive polymer layer 3162. The carbonaceous layer 3166 may be applied in direct, physical contact with the conductive polymer layer 3164, and the metallization layer 3168 may be applied on the conductive polymer layer 3164 by being in direct, physical contact with the carbonaceous layer 3166 thereon. Preferably, the application of the metallization layer 3168 may comprise depositing a diffusion barrier on the conductive polymer layer 3164 (e.g., directly in contact with the carbonaceous layer 3166 thereon) and depositing metal adjacent the diffusion barrier. The carbonaceous layer 3166, if included, may advantageously reduce a contact resistance between the conductive polymer layer 3164 and other components, such as a diffusion barrier layer of the metallization layer 3168. The carbonaceous layer 3166 may include, for example, carbon black, graphite, a carbon-based ink, or a polymeric, and may be applied using a variety of techniques, such as screen printing, inkjet printing, sputter deposition, vacuum deposition, spin coating, doctor blading, or the like. The metallization layer 3168 may be used to provide high-quality electrical conductivity between the respective conductive polymer layer 3164 (acting as the second electrode of the capacitor 110) and the metal terminals 372, 374 for electrical connection of the capacitor 110 with an external circuit. The metallization layer 3168 may include a metal such as Ag, Au, Cu, Pt, Pd, and/or composites or alloys of the aforementioned metals, or in some cases polymers such as epoxies, silicones, or fluoroelastomers. Including a diffusion barrier layer in the metallization layer 3168 may limit infiltration of components from the metallization layer 3168 into the carbonaceous layer 3166 or conductive polymer layer 3164. Example materials for a diffusion barrier layer include, but are not limited to, Ti, W, Cr, Ti—W, TaN, and/or Co—W. The metallization layer 3168, as well as any diffusion barrier layer thereof, may be applied using any suitable techniques, such as vacuum deposition (e.g., sputter deposition).

Within each capacitor stack 311a, 311b, 311c, the conductive substrates 312 serving as the first terminals (e.g., anodes) of the constituent capacitive elements 310, may be electrically connected together (e.g., by conductive spacers 318) and to one of the terminals 372, 322, while the conductive polymer layer serving as the second terminals (e.g., cathodes) may be electrically connected together and to another of the terminals 374, 324. In the illustrated example, the three capacitor stacks 311a, 311b, 311c all make use of different anode terminals 372, 322 so as to service different voltage domains, while all sharing the same cathode terminal 374, 324. Alternatively, conductive spacers 318 may be omitted, in which case the ends of the conductive substrates 312 may simply be pinched together and resistance welded, for example, such that they may be bent downward (or upward) toward the lead frame 370, 380, PCB 320, 390, or other metal terminals.

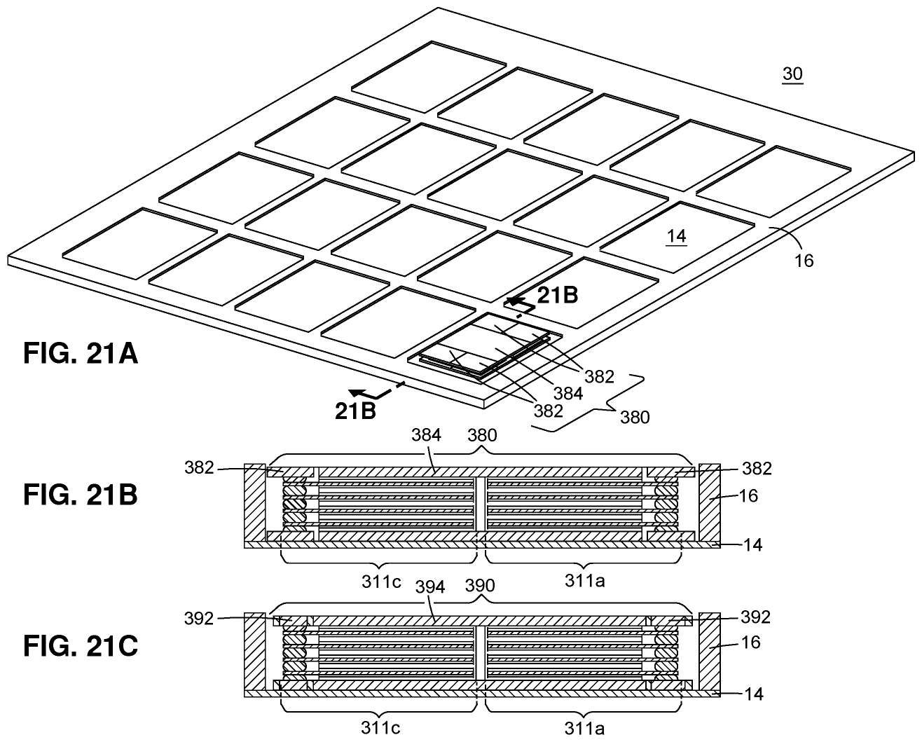

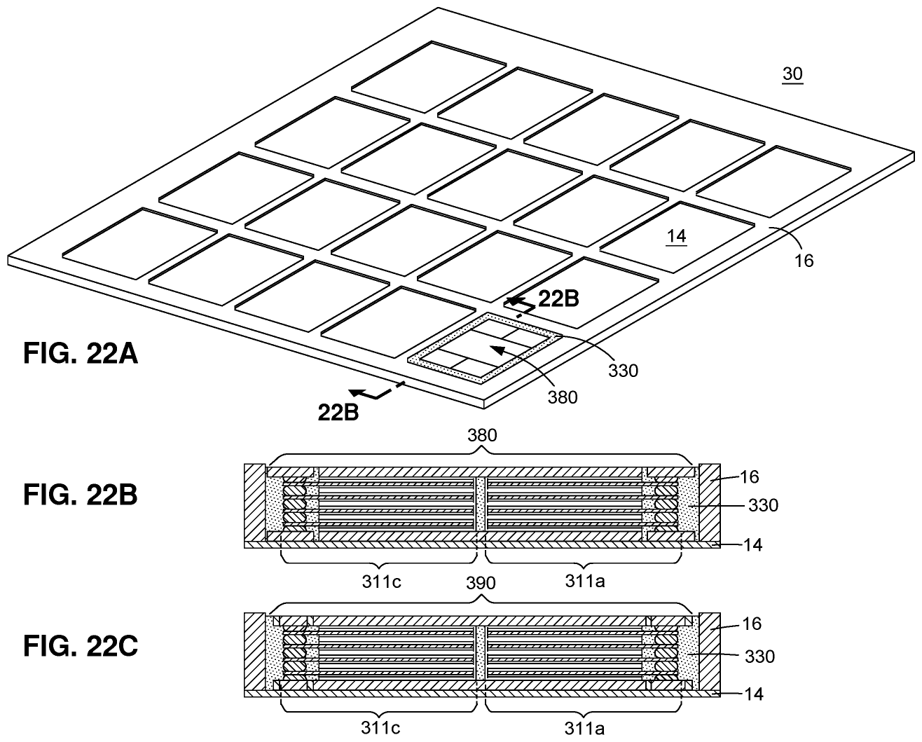

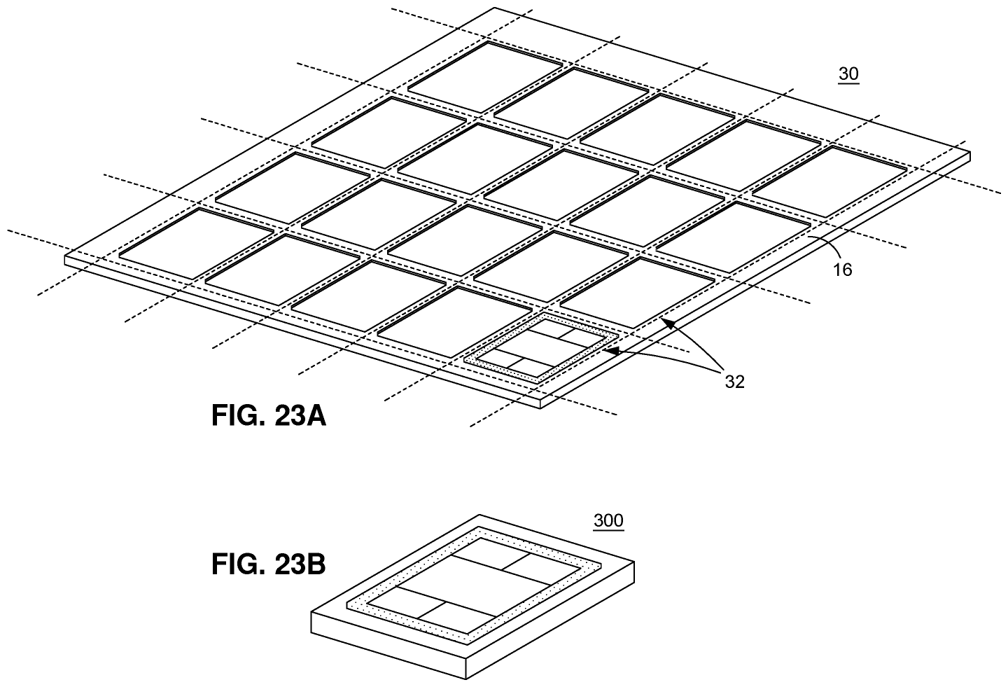

Referring to FIGS. 21A and 21B, a plurality of electrically isolated metal terminals 382, 384, which may be terminals of a lead frame 380 as represented in FIGS. 19A and 19B or discrete terminal pads, may then be provided on top of the stacks of capacitors 311a, 311b, 311c. Alternatively, a PCB 390 having electrically isolated terminals 392, 394 in place of the terminals 382, 384 may be placed on top of the stacks 311a, 311b, 311c. In the depicted layout, four first terminals 382 are provided that are electrically isolated from each other and arranged on either side of the cell 32, and a single second terminal 384 is provided in the middle of the cell 32, matching the arrangement of terminals 372, 374 underneath the capacitors stacks 311a, 311b, 311c. As illustrated in FIGS. 22A-22C, the stacks 311a, 311b, 311c in each cell 32 may then be encapsulated with a polymer layer 330 such as an epoxy resin, the surface of which may be planarized as desired. Alternatively, the encapsulation with the polymer layer 330 may be done prior to the formation of top terminals depicted in FIGS. 21A-21C, in which case vias may be formed in the polymer layer 330 as described above in order to expose and access the buried electrodes of the capacitors 310.

Finally, the tile grid 30 may be diced as represented by the dashed lines in FIG. 23A, thus singulating individual tiles 300 as illustrated in FIG. 23B. The singulated tile 300, like the tiles 100, 100′, 200 described above, may then be embedded in the substrate core 1100 of a package substrate 1000 as shown in FIGS. 5 and 6 and described above.

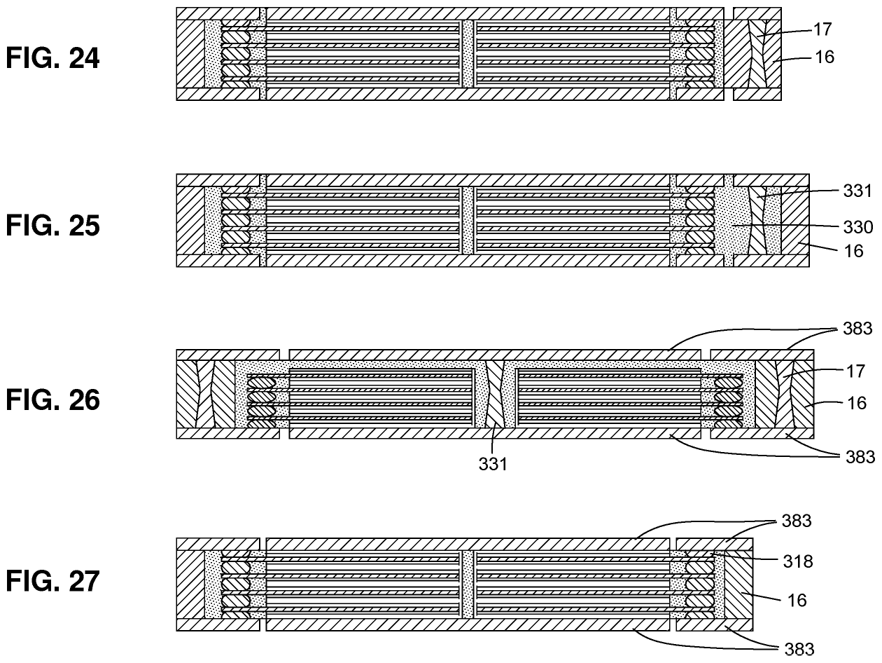

FIGS. 24-29 show additional variants of the tile 300. Referring to FIG. 24, it is contemplated that the tile 300 described herein may include one or more pass-through vias 17 formed within the frame 16. Referring to FIG. 25, the tile 300 may alternatively or additionally include one or more pass-through vias 331 formed within the polymer layer 330. The pass-through vias 17, 331 may comprise a conductive via fill provided within a drilled hole and may allow for pass-through electrical connections as may be needed depending on the particular application.

FIGS. 26 and 27 shows a variant including plated terminal pads 383 provided after encapsulation with the polymer layer 330, in place of the terminals 382 provided prior to encapsulation. The plated terminal pads 383 may be formed by electroplating, for example. Connection to the plated terminal pads 383 may be made by exposing the top of the capacitor stacks 311a, 311b, 311c by mechanical or laser ablation, followed by plating. Alternatively, or additionally, vias 17, 331 may be formed in the frame 16 or in the polymer layer 330 as shown in FIG. 26 in order to electrically connect the bottom and top plated terminal pads 383 to each other (or, in some cases to connect bottom terminals 372, 374 (e.g., of lead frame 370) to top plated terminal pads 383, for example).

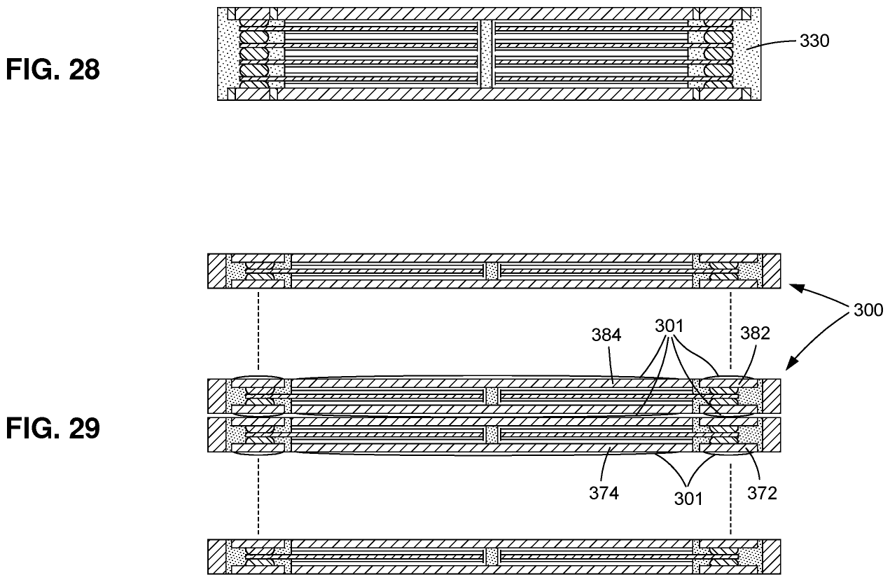

FIG. 28 shows a frameless example that may be the same as the tile 300 described above except that the frame 16 may be completely omitted from the tile array 30. To produce this variant, the cells 32 of the tile grid 30 may be defined arbitrarily by placement of the lead frames 370, PCBs 320, and/or discrete terminals as desired and by arrangement of the stacks of capacitors 310 thereon, rather than by cutout regions of a frame 16. The polymer layer 330 may then be filled over all of the cells 32 at once, and the cells 32 may be singulated by cutting through the polymer layer 330 itself (rather than through the frame 16 as described above).

FIG. 29 is provided to illustrate the possibility of stacking tiles 300 produced as described above in order to build thicker tiles 300 containing more capacitive elements. To this end, after the singulation of cells 32 into tiles 300 as described above, a conductive paste or solder 301 may be disposed on some or all of the lower metal terminals 372, 374, 322, 324 and/or on some or all of the upper metal terminals 382, 384, 392, 394. The lower metal terminals of one tile 300 may then be conductively adhered to the upper metal terminals of another tile 300 to create thicker tiles 300 containing more capacitive elements as desired prior to embedding in package substrate 1000. Advantageously, stacking of the tiles 300 in this way may further reduce the footprint of the resulting stack of tiles 300, which may, for example, allow for increased capacitance within the same area near the integrated circuit to be mounted on the package substrate 1000.

Throughout the above description, the various tiles 100, 100′, 200, 300 are described as containing passive devices such as inductors, capacitors, resistors, IPDs, etc. However, the disclosed embodiments are not necessarily limited to tiles that contain passive devices or that only contain passive devices. For example, a modified tile 100, 100′, 200, 300 (and likewise the cells of a modified tile grid 10, 20, 30) may be provided with active devices instead of or in addition to the passive devices depending on the particular application, with the resulting tile similarly being embeddable and/or stackable as described herein.

The above description is given by way of example, and not limitation. Given the above disclosure, one skilled in the art could devise variations that are within the scope and spirit of the invention disclosed herein. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A tile for embedding components into a package substrate of a semiconductor device, the tile comprising:
a plurality of passive devices, at least two of the passive devices being individually packaged for surface mounting on first sides thereof and having respective second sides opposite the first sides, the first sides of the at least two passive devices being aligned, the second sides of the at least two passive devices being at different heights relative to the aligned first sides; and
a polymer layer surrounding the at least two passive devices and having a planar surface, the planar surface being at a height that is at least as great as the heights of the second sides of the at least two passive devices.

2. The tile of claim 1, further comprising one or more first metal routing layers by which metal terminals on the first sides of the at least two passive devices are electrically connected to metal terminals on a first outer surface of the tile.

3. The tile of claim 2, further comprising one or more second metal routing layers by which metal terminals on the second sides of the at least two passive devices are electrically connected to metal terminals on a second outer surface of the tile opposite the first, the one or more second metal routing layers being electrically connected to the metal terminals on the second sides of one or more of the at least two passive devices by way of one or more conductive vias formed in the polymer layer.

4. The tile of claim 1, further comprising one or more metal routing layers by which metal terminals on the second sides of the at least two passive devices are electrically connected to metal terminals on an outer surface of the tile, the one or more metal routing layers being electrically connected to the metal terminals on the second sides of one or more of the at least two passive devices by way of one or more conductive vias formed in the polymer layer.

5. The tile of claim 1, further comprising a frame containing the plurality of passive devices and the polymer layer.

6. The tile of claim 5, wherein a conductive via is formed within the frame electrically connecting a metal terminal on a first outer surface of the tile to a metal terminal on a second outer surface of the tile opposite the first.

7. The tile of claim 1, wherein a conductive via is formed within the polymer layer electrically connecting a metal terminal on a first outer surface of the tile to a metal terminal on a second outer surface of the tile opposite the first.

8. The tile of claim 1, wherein the plurality of passive devices includes stacked passive devices.

9. The tile of claim 1, further comprising a lead frame on which the at least two passive devices are mounted.

10. The tile of claim 1, further comprising a printed circuit board (PCB) on which the at least two passive devices are mounted.

11. The tile of claim 10, further comprising one or more first metal routing layers by which metal terminals on the first sides of the at least two passive devices are electrically connected to metal terminals on a first outer surface of the tile by way of one or more conductive vias formed in the PCB.

12. The tile of claim 11, further comprising one or more second metal routing layers by which metal terminals on the second sides of the at least two passive devices are electrically connected to metal terminals on a second outer surface of the tile opposite the first, the one or more second metal routing layers being electrically connected to the metal terminals on the second sides of one or more of the at least two passive devices by way of one or more conductive vias formed in the polymer layer.

13. The tile of claim 10, wherein the plurality of passive devices includes one or more passive devices embedded in the PCB.

14. The tile of claim 10, wherein a conductive via is formed within the PCB electrically connecting opposing sides of the PCB.

15. The tile of claim 10, further comprising a frame containing the plurality of passive devices, the polymer layer, and the PCB.

16. The tile of claim 15, wherein a conductive via is formed within the frame electrically connecting a metal terminal on a first outer surface of the tile to a metal terminal on a second outer surface of the tile opposite the first.

17. A package substrate of a semiconductor device, the package substrate comprising:
a substrate core; and
a tile embedded in the substrate core, the tile including:
a plurality of passive devices, at least two of the passive devices being individually packaged for surface mounting on first sides thereof and having respective second sides opposite the first sides, the first sides of the at least two passive devices being aligned, the second sides of the at least two passive devices being at different heights relative to the aligned first sides; and
a polymer layer surrounding the plurality of passive devices and having a planar surface, the planar surface being at a height that is at least as great as the heights of the second sides of the at least two passive devices.

18. The package substrate of claim 17, wherein a thickness of the tile matches a thickness of the substrate core.

19. The package substrate of claim 17, wherein the plurality of passive devices define a plurality of decoupling capacitors in relation to an integrated circuit to be mounted on the package substrate.

20. The package substrate of claim 17, wherein the plurality of passive devices define an integrated voltage regulator (IVR) in relation to an integrated circuit to be mounted on the package substrate.

21. A tile grid for manufacturing a plurality of tiles for embedding components into a package substrate of a semiconductor device, the tile grid comprising:
a frame having a plurality of cutout regions defining a plurality of cells, each of the cells containing a plurality of passive devices; and
a plurality of polymer layers respectively filling the plurality of cells, each of the polymer layers surrounding the respective plurality of passive devices and having a planar surface.

22. The tile grid of claim 21, wherein,
in each of the cells, at least two of the passive devices are individually packaged for surface mounting on first sides thereof and have respective second sides opposite the first sides, the first sides of the at least two passive devices being aligned, the second sides of the at least two passive devices being at different heights relative to the aligned first sides, and,
in each of the cells, the planar surface of the polymer layer is at a height that is at least as great as the heights of the second sides of the at least two passive devices.

23. The tile grid of claim 21, wherein, in each of the cells, the plurality of passive devices includes a stack of two or more unpackaged capacitors.

24. The tile grid of claim 23, wherein each of the cells further contains a plurality of metal terminals, the plurality of metal terminals including:
two or more first metal terminals electrically isolated from each other and electrically connected to respective first electrodes of the two or more unpackaged capacitors; and
a shared second metal terminal electrically connected to the second electrodes of the two or more unpackaged capacitors.

25. A method of manufacturing a tile for embedding components into a package substrate of a semiconductor device, the method comprising:
surrounding at least two passive devices with a polymer layer, the at least two passive devices being individually packaged for surface mounting on first sides thereof and having respective second sides opposite the first sides, the first sides of the at least two passive devices being aligned, the second sides of the at least two passive devices being at different heights relative to the aligned first sides, the polymer layer having a planar surface at a height that is at least as great as the heights of the second sides of the at least two passive devices; and
singulating a tile comprising the polymer layer and a plurality of passive devices including the at least two passive devices.
